(19) United States
(12) Patent Application Publication
(10) Pub. No.: US 2025/0285922 A1
(43) Pub. Date: Sep. 11, 2025

(54) METHOD FOR MANUFACTURING GROUP III NITRIDE POWER SEMICONDUCTOR DEVICE USING EPITAXIAL DIES

(71) Applicant: WAVELORD CO., LTD, Hwaseong-si (KR)

(72) Inventors: Juneo SONG, Suwon-si (KR); Hyeong Seon YUN, Paju-si (KR); Young Hun HAN, Osan-si (KR); Ji Hyung MOON, Gunpo-si (KR)

(73) Assignee: WAVELORD CO., LTD, Hwaseong-si (KR)

(21) Appl. No.: 18/860,658

(22) PCT Filed: Dec. 13, 2023
(86) PCT No.: PCT/KR2023/020519

§ 371 Date: Oct. 27, 2024

(30) Foreign Application Priority Data
Dec. 20, 2022 (KR) 10-2022-0179180
Jan. 19, 2023 (KR) 10-2023-0007913

(51) Int. Cl. H01L 21/78; C30B 25/02; C30B 29/40; C30B 33/00; H01L 21/02

(52) U.S. Cl. CPC H01L 21/7806; C30B 25/02; C30B 29/403; C30B 33/00; H01L 21/0254

(57) ABSTRACT

The present invention relates to a method for manufacturing a Group III nitride power semiconductor device using epitaxial dies, by which a high-quality Group III nitride power semiconductor device can be manufacturing by cutting a substrate having epitaxially grown thereon a Group III nitride semiconductor layer so as to form a plurality of epitaxial dies, and then binding the formed plurality of epitaxial dies to a highly heat-dissipating support substrate.

### TECHNICAL FIELD

The present invention relates to a method of manufacturing a group III nitride power semiconductor device using epitaxy dies, and more specifically, to a method of manufacturing a group III nitride power semiconductor device using epitaxy dies, which may manufacture a high-quality group III nitride power semiconductor device by cutting a substrate on which a group III nitride semiconductor layer is epitaxially grown to manufacture a plurality of epitaxy dies and then bonding the plurality of manufactured epitaxy dies to a high heat dissipation support substrate.

### BACKGROUND ART

Sapphire growth substrate wafers, on which high-quality epitaxial thin film of group III nitride semiconductors including gallium nitride (GaN) can be grown, have been widely used for development and mass production in the optical device field including light emitting diodes (LEDs) and laser diodes (LDs), and practical verification of epitaxy and chip quality has already been completed. In particular, an epitaxy quality level of a group III nitride semiconductor including gallium nitride (GaN) grown on a sapphire growth substrate has been improved to a level that can satisfy the performance and quality required for next-generation high-frequency or switching devices. In addition, since it is currently possible to supply growth substrate wafers of up to 12 inches, chip dies such as group III nitride power semiconductor-based transistors (a high electron mobility transistor (HEMT), a junction field effect transistor (JFET), and a metal-oxide-semiconductor FET (MOSFET)) and diodes (PN and Schottky) may be manufactured with high cost-effectiveness.

However, since there is a disadvantage that the thermal conductivity (35 W/mK) of sapphire is much lower than that of silicon (Si), aluminum nitride (AlN), silicon carbide (SiC), etc., the large amount of heat generated when high-output power semiconductors that handle a high voltage or high current are operated may not be easily dissipated, resulting in a fatal weakness in terms of the performance and long-term reliability of group III nitride power semiconductor devices manufactured on the sapphire wafer.

Currently, among high-output power semiconductor devices made of the group III nitride semiconductors including gallium nitride (GaN), high-frequency devices for a communication device are designed, developed, and manufactured on a silicon carbide (SiC) growth substrate, and switching devices for an electrical/electronic device are designed, developed, and manufactured on a silicon (Si) growth substrate wafer.

Semi-insulating silicon carbide (SiC) growth substrate wafers have the best heat dissipation performance among materials used as single-crystal semiconductor wafers, and thus have a great advantage in dissipating the large amount of heat generated when an HEMT for a high-frequency communication device is driven, but since the high manufacturing cost of the wafer causes a high-cost issue and the wafer is made of a material that generates tensile stress that causes cracks due to a difference in coefficient of thermal expansion from a gallium nitride (GaN) material, there is a practical difficulty in securing the quality of an epitaxial thin film by increasing a thickness of the gallium nitride (GaN) epitaxial thin film to manufacture power semiconductor devices to have low-density crystal defects.

In addition, silicon (Si) growth substrate wafers have a great advantage in that 12-inch growth substrate wafers may be supplied, there is compatibility with silicon (Si)-based complementary metal-oxide semiconductor (CMOS) fab processes, and material costs and manufacturing costs for power semiconductors are very inexpensive, but there are problems such as melt-back etching occurring on a silicon (Si) surface in a growth process of a group III nitride epitaxy thin film, severe wafer bowing occurring due to tensile stress caused by large differences in lattice constants (LC) and coefficient of thermal expansion (CTE) from a semiconductor layer, and epitaxy cracks, and in severe cases, wafer breakage, and thus there is a disadvantage in growing the group III nitride epitaxy thin film thickly to have low-density crystal defects.

Under the above-described background, to improve the group III nitride power semiconductors in terms of performance, quality, and cost in the related art, the group III nitride power semiconductor device has been manufactured by growing a high-quality group III nitride power semiconductor epitaxy thin film structure on a sapphire initial growth substrate to have low-density crystal defects and then transferring the group III nitride power semiconductor epitaxy thin film onto a support substrate wafer having high heat dissipation characteristics through a wafer-level bonding or wafer to wafer (W2W) process.

However, according to such a conventional technology, typically, since a silicon (Si), silicon carbide (SiC), or aluminum nitride (AlN) final support substrate wafer having high heat dissipation characteristics has a difference in CTE from the sapphire initial growth substrate as large as 2 ppm or more, although it is preferable to perform an annealing process at a predetermined temperature of 300° C. or higher during the W2W bonding process or after the above process is completed, this is realistically impossible.

Therefore, the conventional W2W bonding process generally introduces an intermediate bonding layer between wafers to bond dielectric materials (SiO2, spin on glass (SOG), hydrogen silsesquioxane (HSQ), SiN, SiCN, AlN, SiC, diamond, or Al2O3), and in this case, strict conditions such as zero foreign substances (particles) on the surfaces of the two wafers, minimizing a total thickness variation (TTV), and ensuring that surface roughness is less than 0.5 nm should be satisfied at the same time, which may not be easily implemented.

### DISCLOSURE

### Technical Problem

The present invention is intended to solve the above conventional problems and is directed to providing a method of manufacturing a group III nitride power semiconductor device using epitaxy dies, which may manufacture a high-quality group III nitride power semiconductor device by cutting a substrate on which a group III nitride semiconductor layer is epitaxially grown to manufacture a plurality of epitaxy dies and then bonding the plurality of manufactured epitaxy dies to a high heat dissipation support substrate.

### Technical Solution

According to the present invention, the above object is achieved by a method of manufacturing a group III nitride power semiconductor device using epitaxy dies, which includes a first operation of epitaxially growing a semiconductor layer on a growth substrate, a second operation of cutting the growth substrate on which the semiconductor layer is grown to manufacture a plurality of dies, a third operation of bonding the semiconductor layer of the die to a support substrate through a bonding layer, a fourth operation of separating the growth substrate from the semiconductor layer, and a fifth operation of cutting the support substrate to which the semiconductor layer is bonded to manufacture a power semiconductor device.

According to the present invention, the above object is achieved by a method of manufacturing a group III nitride power semiconductor device using epitaxy dies, which includes a first operation of epitaxially growing a semiconductor layer on a growth substrate, a second operation of cutting the growth substrate on which the semiconductor layer is grown to manufacture a plurality of dies, a third operation of adhering the semiconductor layer of the die to a temporary substrate through an adhesive layer, a fourth operation of separating the growth substrate from the semiconductor layer, a fifth operation of bonding a surface of the semiconductor layer from which the growth substrate is separated to a support substrate through a bonding layer, a sixth operation of separating the temporary substrate from the adhesive layer, a seventh operation of etching and removing the adhesive layer, and an eighth operation of cutting the support substrate to which the semiconductor layer is bonded to manufacture a power semiconductor device.

According to the present invention, the above object is achieved by a method of manufacturing a group III nitride power semiconductor device using epitaxy dies, which includes a first operation of epitaxially growing a semiconductor layer on a growth substrate, a second operation of adhering the semiconductor layer to a temporary substrate through an adhesive layer, a third operation of separating the growth substrate from the semiconductor layer, a fourth operation of cutting the temporary substrate to which the semiconductor layer is adhered to manufacture a plurality of dies, a fifth operation of bonding a surface of the semiconductor layer of the die from which the growth substrate is separated to a support substrate through a bonding layer, a sixth operation of separating the temporary substrate from the adhesive layer, a seventh operation of etching and removing the adhesive layer, and an eighth operation of cutting the support substrate to which the semiconductor layer is bonded to manufacture a power semiconductor device.

### Advantageous Effects

According to the present invention, unlike the conventional wafer to wafer (W2W) bonding method, by cutting a substrate on which a group III nitride semiconductor layer is grown epitaxially to manufacture a plurality of epitaxy dies and then bonding these epitaxy dies to a high heat dissipation support substrate (die to wafer (D2W)), it is possible to minimize defects due to a difference in coefficient of thermal expansion (CTE) between a semiconductor layer and a final support substrate, such as wafer bowing, thereby implementing a group III nitride power semiconductor device such as a transistor or diode that has high quality, high thermal conductivity, and high cost-effectiveness.

In addition, according to the present invention, since a reinforcement layer including a bonding reinforcement layer and a compressive stress layer, which have high-resistance insulation characteristics, can be formed on an upper surface (between a bonding layer and the semiconductor layer) or lower surface (between the bonding layer and a final support substrate) of the bonding layer to effectively block a leakage current to a lower support substrate (or in a horizontal direction), a low-quality and high-resistance gallium nitride (GaN) buffer layer doped with iron (Fe) or carbon (C) is not needed. Therefore, it is possible to secure a high electron mobility transistor (HEMT) active region such as a high-quality gallium nitride (GaN) channel layer and aluminum nitride gallium (AlGaN) barrier layer by omitting the low-quality and high-resistance gallium nitride (GaN) buffer layer, thereby significantly improving the reliability and performance of a power semiconductor device.

In addition, according to the present invention, since it is not necessary to directly grow a melt-back etching prevention layer and a compressive stress layer that are essential for the growth substrate of the related art, a high-quality aluminum nitride gallium (AlGaN) barrier layer can be grown on a high-quality group III nitride semiconductor layer. In addition, compared to a method of directly growing the melt-back etching prevention layer and the compressive stress layer on the conventional silicon (Si) growth substrate, a low-defect and high-quality group III nitride semiconductor layer can be grown. In addition, since the growth of the melt-back etching prevention layer and the compressive stress layer is omitted, it is possible to implement the group III nitride power semiconductor structure (particularly, an HEMT) having a smaller thickness than before, thereby improving material costs and yield.

Meanwhile, the effects of the present invention are not limited to the above-described effects, and may include various effects within a range that is apparent to those skilled in the art from the following descriptions.

### DESCRIPTION OF DRAWINGS

FIG. 1 is a flowchart of a method of manufacturing a group III nitride power semiconductor device using epitaxy dies according to a first embodiment of the present invention.

FIG. 2 shows a process of manufacturing a group III nitride power semiconductor device using epitaxy dies according to the first embodiment of the present invention.

FIG. 3 shows a reinforcement layer differently disposed on the group III nitride power semiconductor device manufactured according to the first embodiment of the present invention.

FIG. 4 is a flowchart of a method of manufacturing a group III nitride power semiconductor device using epitaxy dies according to a second embodiment of the present invention.

FIG. 5 shows a process of manufacturing a group III nitride power semiconductor device using epitaxy dies according to the second embodiment of the present invention.

FIG. 6 is a flowchart of a method of manufacturing a group III nitride power semiconductor device using epitaxy dies according to a third embodiment of the present invention.

FIG. 7 shows a process of manufacturing a group III nitride power semiconductor device using epitaxy dies according to the third embodiment of the present invention.

FIG. 8 shows a reinforcement layer differently disposed on the group III nitride power semiconductor device manufactured according to the second embodiment or third embodiment of the present invention.

### MODES OF THE INVENTION

Hereinafter, some embodiments of the present invention will be described in detail with reference to exemplary drawings. In adding reference numerals to components in each drawing, it should be noted that the same components have the same reference numerals as much as possible even when they are illustrated in different drawings.

In addition, in describing embodiments of the present invention, detailed descriptions of related known configurations or functions will be omitted when it is determined that the detailed descriptions obscure the understanding of the embodiments of the present invention.

In addition, terms such as first, second, A, B, (a), and (b) may be used to describe components of the embodiments of the present invention. These terms are only for the purpose of distinguishing one component from another component, and the nature, sequence, order, or the like of the corresponding component is not limited by the terms.

A method S100 of manufacturing a group III nitride power semiconductor device using epitaxy dies according to a first embodiment of the present invention will now be described in detail with reference to the accompanying drawings.

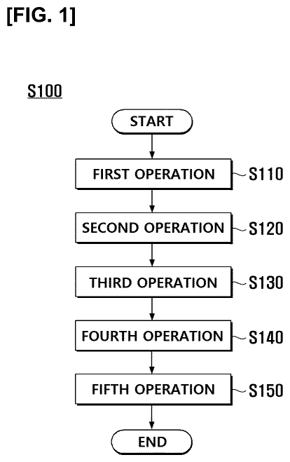

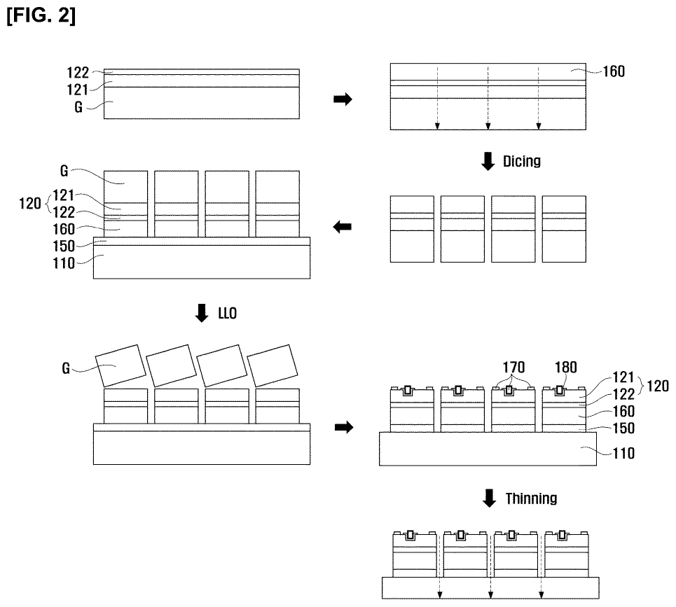

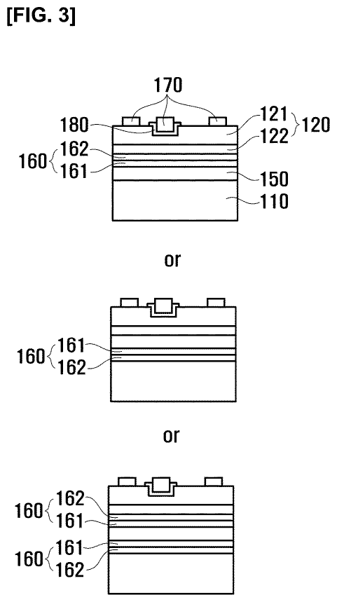

FIG. 1 is a flowchart of a method of manufacturing a group III nitride power semiconductor device using epitaxy dies according to the first embodiment of the present invention, FIG. 2 shows a process of manufacturing a group III nitride power semiconductor device using epitaxy dies according to the first embodiment of the present invention, and FIG. 3 shows a reinforcement layer 160 differently disposed on the group III nitride power semiconductor device manufactured according to the first embodiment of the present invention.

As shown in FIGS. 1 and 2, the method S100 of manufacturing a group III nitride power semiconductor device using epitaxy dies according to the first embodiment of the present invention includes a first operation S110, a second operation S120, a third operation S130, a fourth operation S140, and a fifth operation S150.

In the present invention, an initial growth substrate G is an optically transparent and high-temperature heat-resistant substrate through which a laser beam (single wavelength light) may be 100% transmitted (theoretically) without absorption in a laser lift off (LLO) process to be described below, and a material such as sapphire (α-phase Al2O3), ScMgAlO4, 4H-SiC, or 6H-SiC is preferably used preferentially. In addition, the initial growth substrate G preferably has a protrusion shape (e.g., a patterned sapphire substrate (PSS)) patterned regularly or irregularly in various dimensions (size and shape) in microscale or nanoscale to minimize crystal defects inside the group III nitride semiconductor thin film grown thereon.

In addition, a final support substrate 110 is a substrate that supports a buffer layer 121 and a barrier layer 122 after undergoing each operation of the method S100 of manufacturing a group III nitride power semiconductor device using epitaxy dies according to the first embodiment of the present invention. The final support substrate 110 is preferably provided as a final silicon (Si) support substrate 110 having high heat dissipation performance, and the final silicon (Si) support substrate 110 may be single-crystalline, polycrystalline, or amorphous and may be made of silicon (Si) having a (111) crystal face, a (110) crystal face, or a (100) crystal face. Furthermore, in addition to the above-described silicon (Si), at least one material selected from materials including diamond, silicon carbide (SiC), aluminum nitride (AlN), and sapphire may be included. In particular, the diamond, silicon carbide (SiC), and aluminum nitride (AlN) may be single-crystalline or polycrystalline.

The first operation S110 is an operation of epitaxially growing a semiconductor layer 120 on the initial growth substrate G.

More specifically, the first operation S110 is an operation of forming a sacrificial layer 130 on the initial growth substrate G and then growing a high-quality group III nitride semiconductor layer 120 (including the group III nitride semiconductor buffer layer 121 and the barrier layer 122) on the sacrificial layer 130 as a single layer or multiple layers and specifically, is an operation of growing a high-quality buffer layer 121 on the sacrificial layer 130 formed on the initial growth substrate G as a single layer or multiple layers and growing a high-quality barrier layer 122 on the buffer layer 121 as a single layer or multiple layers. Meanwhile, the semiconductor layer 120 of the present invention is not limited to the buffer layer 121 and the barrier layer 122, and various layers (e.g., a passivation layer and a p-type semiconductor layer for hole injection) for implementing a power semiconductor device structure such as a transistor or a diode may be formed without limitation.

Here, the sacrificial layer 130 is a layer required for growing a high-quality group III nitride semiconductor layer 120 (including the group III nitride semiconductor buffer layer 121 and the barrier layer 122), and is made of a material capable of sacrificial separation by thermal-chemical decomposition reactions caused by a laser beam, and for example, the sapphire initial growth substrate G may contain indium gallium nitride (InGaN), gallium nitride (GaN), aluminum gallium nitride (AlGaN), and indium aluminum nitride (InAlN). The sacrificial layer 130 is grown directly on the initial growth substrate G to minimize crystal defects in the semiconductor layer 120 and serves as a buffer.

In this case, a single layer or multiple layers made of a high-quality group III nitride (GaN, AlGaN, AlN, InAlN), which is a highly electrical resistive insulator, as a layer other than the high-quality buffer layer 121 and the high-quality barrier layer 122, may be deposited (grown) on the sacrificial layer 130.

In addition, the group III nitride semiconductor layer 120, that is, the group III nitride semiconductor buffer layer 121 and barrier layer 122, may be made of a single layer or multiple layers of group III nitride semiconductors and may be made of gallium nitride (GaN), aluminum gallium nitride (AlGaN), aluminum nitride (AlN), aluminum gallium nitride/gallium nitride (AlGaN/GaN SLs) with a superlattice structure, aluminum nitride/gallium nitride (AlN/GaN SLs) with a superlattice structure, aluminum gallium nitride/aluminum nitride (AlGaN/AlN SLs) with a superlattice structure, indium gallium nitride (InGaN), indium aluminum nitride (InAlN), gallium nitride/indium aluminum nitride (GaN/InAlN), aluminum scandium nitride (AlScN), gallium nitride/aluminum scandium nitride (GaN/AlScN), etc., which have high-temperature (HT) and high-resistance (HR) characteristics. A critical quality factor for the group III nitride semiconductor layer 120 is reducing the density of fatal crystal defects, that is, threading dislocations (present in a vertical direction with respect to the initial growth substrate G) (≤Low 108/cm2).

Meanwhile, since a surface of the semiconductor layer 120 (i.e., a surface of the barrier layer 122) formed on the initial growth substrate G and a surface of the semiconductor layer 120 (i.e., a surface of the buffer layer 121) subsequently transferred onto the final support substrate 110 are inverted, a total thickness variation (TTV) should be minimized, the surface roughness should be minimized (RMS<1 nm), and a foreign substance (particles) such as an organic substance and a metallic substance should be minimized after growth so that a predetermined preferred surface of the semiconductor layer 120 may be formed, and as a growth process that can achieve the above, all processes using metal organic chemical vapor deposition (MOCVD) and molecular beam epitaxy (MBE) devices are possible, but the growth process is preferably performed through a process with a relatively low growth temperature. For example, in the case of a gallium nitride (GaN) semiconductor layer 120, a gallium polarity (Ga-polarity) or nitrogen polarity (N-polarity) surface may be selectively controlled according to the surface treatment and growth conditions of the initial growth substrate G. Typically, when the group III nitride semiconductor layer 120 is grown on the sapphire initial growth substrate G wafer in an MOCVD chamber, while the group III nitride semiconductor layer 120 has a surface with a metal (M: Ga, Al, In) polarity with 3 valence electrons, an interface in direct contact with the sapphire initial growth substrate G has a nitrogen polarity with 5 valence electrons.

The second operation S120 is an operation of cutting the initial growth substrate G on which the semiconductor layer 120 is grown at preset intervals to manufacture a plurality of epitaxy dies. That is, the epitaxial die in the present invention means that the initial growth substrate G on which the semiconductor layer 120 is epitaxially grown is cut (diced) into a plurality of dies and sorted according to characteristics. Meanwhile, in the second operation S120, an epitaxial protective layer may be formed, and some electrodes 170 may be formed in advance.

Typically, since diamond, a silicon (Si), silicon carbide (SiC), or aluminum nitride (AlN) final support substrate 110 wafer having high heat dissipation characteristics has a difference in CTE from the sapphire initial growth substrate G as large as 2 ppm or more, although it is preferable to perform an annealing process at a predetermined temperature of 300° C. or higher during the W2W bonding process or after the above process is completed, this is realistically impossible. Therefore, the W2W bonding process generally introduces an intermediate bonding layer between wafers to bond dielectric materials (SiO2, spin on glass (SOG), hydrogen silsesquioxane (HSQ), SiN, SiCN, AlN, SiC, diamond, or Al2O3), and in this case, strict conditions such as zero foreign substances (particles) on the surfaces of the two wafers, minimizing a total thickness variation (TTV), and ensuring that surface roughness is less than 0.5 nm should be satisfied at the same time, which may not be easily implemented.

Therefore, in the present invention, first, the plurality of epitaxy dies may be manufactured by cutting the initial growth substrate G on which the semiconductor layer 120 is grown, and then the plurality of epitaxy dies may each be bonded on the final support substrate 110 wafer having high heat dissipation performance (die to wafer (D2W)), and therefore, the effect of the CTE between the small epitaxy dies and the relatively large final support substrate 110 wafer can be minimized, making it easy to manufacture a high-quality group III nitride power semiconductor device.

The third operation S130 is an operation of bonding each of the semiconductor layers 120 of the plurality of epitaxy dies to the final support substrate through a bonding layer 150. That is, the third operation S130 is an operation of turning over the plurality of epitaxy dies and pressing and bonding the semiconductor layers 120 to the final support substrate 110 at a temperature of lower than 300° C. For example, the semiconductor layer 120 may be bonded to the final support substrate 110 by forming a first bonding layer on the semiconductor layer 120, that is, the barrier layer 122, forming a second bonding layer on the final support substrate 110, and then bonding the first bonding layer to the second bonding layer to form the bonding layer 150, and the semiconductor layer 120 may be bonded to the final support substrate 110 after the bonding layer 150 is formed only on the semiconductor layer 120 or the final support substrate 110.

Conventionally, epitaxy wafer bowing occurs due to thermo-mechanical induced tensile stress caused by the differences in LC and CTE between the initial growth substrate G and the group III nitride semiconductor, but the epitaxy die bonded to the final support substrate 110 of the present invention may be in a stress-relieved state, thereby minimizing wafer bowing to almost zero. In this case, it is possible to minimize stress by setting a bonding process temperature to about room temperature and performing the process, thereby further minimizing wafer bowing.

In addition, for the bonding layer 150, a dielectric material whose properties do not change and which has excellent thermal conductivity in the MOCVD chamber (at a temperature of 1000° C. or higher and in a reducing atmosphere) in which the group III nitride semiconductor is grown may be preferentially selected, and for example, silicon oxide (SiO2, 0.8 ppm), silicon nitride (SiNx, 3.8 ppm), silicon carbon nitride (SiCN, 3.8 to 4.8 ppm), aluminum nitride (AlN, 4.6 ppm), silicon carbide (SiC, 4.2 ppm), diamond (1.2 ppm), aluminum oxide (Al2O3, 6.8 ppm) may be selected, and furthermore, a flowable oxide (FOx) such as SOG (liquid SiO2) or HSQ may be selected to improve surface roughness.

Meanwhile, the reinforcement layer 160 may be formed between the bonding layer 150 and the semiconductor layer 120 or between the bonding layer 150 and the final support substrate 110.

In this case, when the reinforcement layer 160 is formed between the bonding layer 150 and the semiconductor layer 120, as shown in FIG. 2, the first operation S110 may include epitaxially growing the semiconductor layer 120 on the initial growth substrate G and then forming the reinforcement layer 160 on the semiconductor layer 120, the second operation S120 may include cutting the initial growth substrate G on which the reinforcement layer 160 and the semiconductor layer 120 are formed to manufacture the plurality of epitaxy dies, and the third operation S130 may include bonding the reinforcement layer 160 of the plurality of epitaxy dies to the final support substrate 110 through the bonding layer 150 (see the top figure of FIG. 3).

In addition, although a case where the reinforcement layer 160 is formed between the bonding layer 150 and the final support substrate 110 is not shown, in the third operation S130, the semiconductor layers 120 of the plurality of epitaxy dies may be bonded to the reinforcement layer 160 through the bonding layer 150 by forming the reinforcement layer 160 on the final support substrate 110 and then forming the bonding layer 150 on the reinforcement layer 160 (see the middle figure of FIG. 3).

Here, more specifically, the reinforcement layer 160 includes a bonding reinforcement layer 161 and a compressive stress layer 162.

The bonding reinforcement layer 161 is a layer that is formed in contact with the bonding layer 150 and introduced to increase the bonding strength with the bonding layer 150 when the semiconductor layer 120 is bonded to the final support substrate 110 through the bonding layer 150, and a material constituting the bonding reinforcement layer 161 may include silicon oxide (SiO2), silicon nitride (SiNx), silicon carbon nitride (SiCN), SOG, HSQ, etc.

The compressive stress layer 162 is a layer that is formed on the bonding reinforcement layer 161 to induce compressive stress and is made of a dielectric material with a value larger than the CTE of the final support substrate 110, for example, a material that induces compressive stress to relieve tensile stress, such as aluminum nitride (AlN, 4.6 ppm), aluminum nitride oxide (AlNO, 4.6 to 6.8 ppm), aluminum oxide (Al2O3, 6.8 ppm), silicon carbide (SiC, 4.8 ppm), silicon carbide nitride (SiCN, 3.8 to 4.8 ppm), gallium nitride (GaN, 5.6 ppm), gallium nitride oxide (GaNO, 5.6 to 6.8 ppm), which serves to guide the quality improvement of products through stress control.

Meanwhile, as shown in FIG. 3, in the present invention, in some cases, the reinforcement layer 160 may be disposed between the bonding layer 150 and the semiconductor layer 120 or formed between the bonding layer 150 and the final support substrate 110, and the reinforcement layer 160 may be formed between the bonding layer 150 and the semiconductor layer 120 and between the bonding layer 150 and the final support substrate 110. In addition, the bonding reinforcement layer 161 or the compressive stress layer 162 may be omitted from the reinforcement layer 160, and a case where the reinforcement layer 160 between the bonding layer 150 and the final support substrate 110 is omitted and the bonding layer 150 is directly bonded to the final support substrate 110 may be a structure in which a material having a larger CTE than the final support substrate 110, such as silicon (Si), is deposited on the bonding layer 150 to induce compressive stress together with a bonding function.

The fourth operation S140 is an operation of separating the initial growth substrate G from the buffer layer 121 using an LLO technique. The buffer layer 121 exposed by separating the initial growth substrate G has a nitrogen polar surface (N-polar surface).

Here, the LLO technique is a technique of separating an epitaxy-grown layer from the initial growth substrate G by irradiating a back surface of the transparent initial growth substrate G with an ultraviolet (UV) laser beam having a uniform optical output and beam profile, and a single wavelength. When the initial growth substrate G is separated, the inside of the semiconductor layer 120 transferred onto the final support substrate 110 is in a state in which the stress is completely relieved and maintains a flat state together with the final support substrate 110. Then, planarization is achieved by removing the sacrificial layer 130 damaged due to the separation of the initial growth substrate G, contaminated surface residues, a low-quality single crystalline thin film region, etc. through chemical mechanical polishing (CMP), dry etching, etc.

The fifth operation S150 is an operation of forming a plurality of electrodes 170 on each epitaxy die according to the power semiconductor structure such as a transistor (three electrodes 170) or a diode (two electrodes 170) on the buffer layer 121 of the bonded semiconductor layer 120, forming a passivation layer 180 as needed, then performing annealing for an ohmic contact or Schottky contact, and then thinning and cutting the final support substrate 110 to manufacture a power semiconductor device, which means a plurality of chip dies or IC dies.

A group III nitride power semiconductor device manufactured by the method S100 of manufacturing a group III nitride power semiconductor device using epitaxy dies according to the first embodiment of the present invention may have a structure in which the final support substrate 110, the bonding layer 150, the barrier layer 122, and the buffer layer 121 are sequentially stacked, have a structure in which the reinforcement layer 160 is formed between the bonding layer 150 and the final support substrate 110 or between the bonding layer 150 and the barrier layer 122, and have a structure in which the plurality of electrodes 170 or the passivation layer 180 is formed on an upper surface of the buffer layer 121.

A method S200 of manufacturing a group III nitride power semiconductor device using epitaxy dies according to a second embodiment of the present invention will now be described in detail with reference to the accompanying drawings.

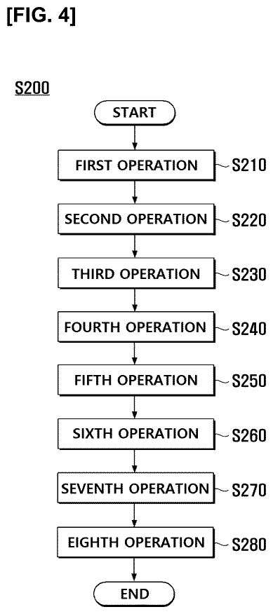

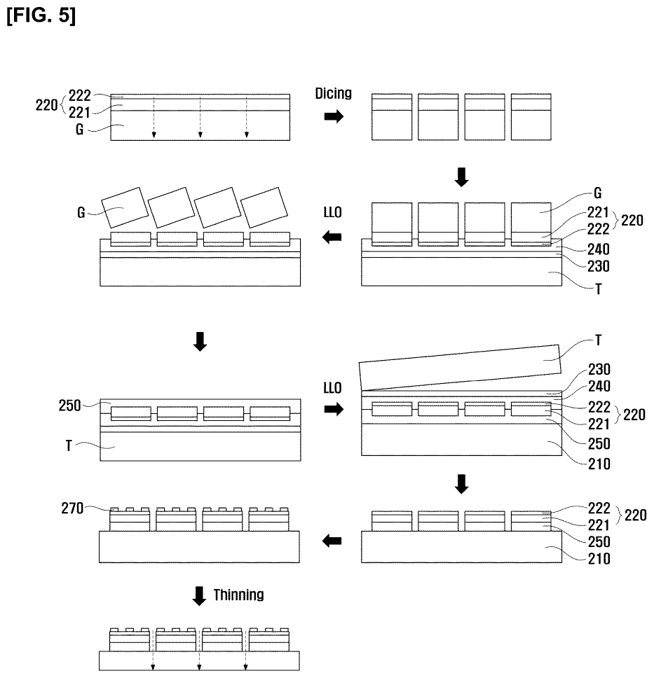

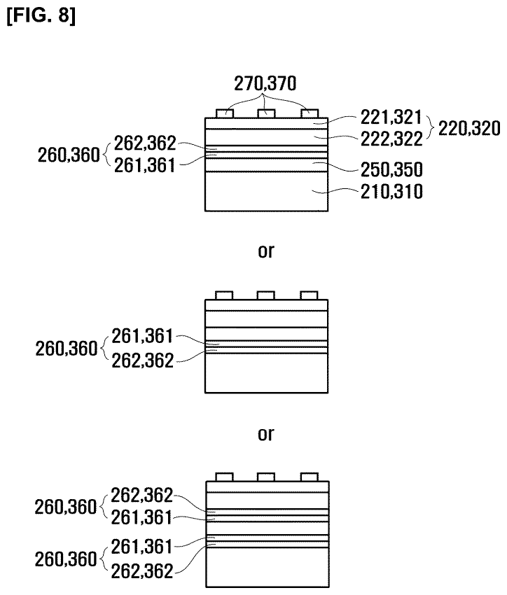

FIG. 4 is a flowchart of a method of manufacturing a group III nitride power semiconductor device using epitaxy dies according to a second embodiment of the present invention, FIG. 5 shows a process of manufacturing a group III nitride power semiconductor device using epitaxy dies according to the second embodiment of the present invention, and FIG. 8 shows a reinforcement layer 260 differently disposed on the group III nitride power semiconductor device manufactured according to the second embodiment or third embodiment of the present invention.

As shown in FIGS. 4 and 5, the method S200 of manufacturing a group III nitride power semiconductor device using epitaxy dies according to the second embodiment of the present invention includes a first operation S210, a second operation S220, a third operation S230, a fourth operation S240, a fifth operation S250, a sixth operation S260, a seventh operation S270, and an eighth operation S280.

In the present invention, the initial growth substrate G is an optically transparent and high-temperature heat-resistant substrate through which a laser beam (single wavelength light) may be 100% transmitted (theoretically) without absorption in an LLO process to be described below, and a material such as sapphire (α-phase Al2O3), ScMgAlO4, 4H-SiC, or 6H-SiC is preferably used. In addition, the initial growth substrate G preferably has a protrusion shape (e.g., a PSS) patterned regularly or irregularly in various dimensions (size and shape) in microscale or nanoscale to minimize crystal defects inside the group III nitride semiconductor thin film grown thereon.

In addition, an intermediate temporary substrate T has a CTE that is the same as or similar to that of a final support substrate 210 to be described below and at the same time, is made of an optically transparent material through which a laser beam (single wavelength light) may be 100% transmitted (theoretically) without absorption in an LLO process to be described below, and it is preferable that the difference in CTE from the final support substrate 210 does not exceed the maximum of 2 ppm. Sapphire is preferred as a material for the intermediate temporary substrate T, which satisfies the above, and silicon carbide (SiC) or glass whose CTE is adjusted to have a difference of 2 ppm or less from the support substrate 210 may be contained.

In addition, the final support substrate 210 is a substrate that supports a buffer layer 221 and a barrier layer 222 after undergoing each operation of the method S200 of manufacturing a group III nitride power semiconductor device using epitaxy dies according to the second embodiment of the present invention. The final support substrate 210 is preferably provided as the silicon (Si) support substrate 210 having high heat dissipation performance, and the silicon (Si) support substrate 210 may be single-crystalline, polycrystalline, or amorphous and may be made of silicon (Si) having a (111) crystal face, a (110) crystal face, or a (100) crystal face. Furthermore, in addition to the above-described silicon (Si), at least one material selected from materials including diamond, silicon carbide (SiC), aluminum nitride (AlN), and sapphire may be included. In particular, the diamond, silicon carbide (SiC), and aluminum nitride (AlN) may be single-crystalline or polycrystalline.

The first operation S210 is an operation of epitaxially growing a semiconductor layer 220 on the growth substrate G.

More specifically, the first operation S210 is an operation of forming a sacrificial layer 230 on the growth substrate G and then growing a high-quality group III nitride semiconductor layer 220 (including the group III nitride semiconductor buffer layer 221 and barrier layer 222) on the sacrificial layer 230 as a single layer or multiple layers and specifically, is an operation of growing the high-quality buffer layer 221 on the sacrificial layer 230 formed on a growth substrate G as a single layer or multiple layers and growing a high-quality barrier layer 222 on the buffer layer 221 as a single layer or multiple layers. Meanwhile, the semiconductor layer 220 of the present invention is not limited to the buffer layer 221 and the barrier layer 222, and various layers (e.g., a passivation layer and a p-type semiconductor layer for hole injection) for implementing a power semiconductor device structure such as a transistor or a diode may be formed without limitation.

Here, the sacrificial layer 230 is a layer required for growing a high-quality group III nitride semiconductor layer 220 (including the group III nitride semiconductor buffer layer 221 and barrier layer 222), and is made of a material capable of sacrificial separation by thermal-chemical decomposition reactions caused by a laser beam, and for example, the sapphire initial growth substrate G may contain indium gallium nitride (InGaN), gallium nitride (GaN), aluminum gallium nitride (AlGaN), and indium aluminum nitride (InAlN). The sacrificial layer 230 is grown directly on the initial growth substrate G to minimize crystal defects in the semiconductor layer 220 and serves as a buffer.

In this case, a single layer or multiple layers made of a high-quality group III nitride (GaN, AlGaN, AlN, InAlN), which is a highly electrical resistive insulator, as a layer other than the high-quality buffer layer 221 and the high-quality barrier layer 222, may be deposited (grown) on the sacrificial layer 230.

In addition, the group III nitride semiconductor layer 220, that is, the group III nitride semiconductor buffer layer 221 and barrier layer 222, may be made of a single layer or multiple layers of group III nitride semiconductors and may be made of gallium nitride (GaN), aluminum gallium nitride (AlGaN), aluminum nitride (AlN), aluminum gallium nitride/gallium nitride (AlGaN/GaN SLs) with a superlattice structure, aluminum nitride/gallium nitride (AlN/GaN SLs) with a superlattice structure, aluminum gallium nitride/aluminum nitride (AlGaN/AlN SLs) with a superlattice structure, indium gallium nitride (InGaN), indium aluminum nitride (InAlN), gallium nitride/indium aluminum nitride (GaN/InAlN), aluminum scandium nitride (AlScN), gallium nitride/aluminum scandium nitride (GaN/AlScN), etc., which have high-temperature (HT) and high-resistance (HR) characteristics. A critical quality factor of the group III nitride semiconductor layer 220 is the reduced density of fatal crystal defects, that is, threading dislocations (present in a vertical direction with respect to the initial growth substrate G) (≤Low 108/cm2).

Meanwhile, since a surface of the semiconductor layer 220 (i.e., a surface of the barrier layer 222) formed on the growth substrate G and a surface of the semiconductor layer 220 (i.e., a surface of the buffer layer 221) subsequently transferred onto the intermediate temporary substrate T are inverted, a total thickness variation (TTV) should be minimized, the surface roughness should be minimized (RMS<1 nm), and a foreign substance (particles) such as an organic substance and a metallic substance should be minimized after growth so that a predetermined preferred surface of the semiconductor layer 220 may be formed, and as a growth process that can achieve the above, all processes using MOCVD and MBE devices are possible, but the growth process is preferably performed through a process with a relatively low growth temperature. For example, in the case of a gallium nitride (GaN) semiconductor layer 220, a gallium polarity (Ga-polarity) or nitrogen polarity (N-polarity) surface may be selectively controlled according to the surface treatment and growth conditions of the growth substrate G. Typically, when the group III nitride semiconductor layer 220 is grown on the sapphire initial growth substrate G wafer in an MOCVD chamber, while the group III nitride semiconductor layer 120 has a surface with a metal (M: Ga, Al, In) polarity with 3 valence electrons, an interface in direct contact with the sapphire initial growth substrate G has a nitrogen polarity with 5 valence electrons. Meanwhile, in the first operation S210, an epitaxial protective layer may be formed, and some electrodes 270 may be formed in advance.

The second operation S220 is an operation of cutting the initial growth substrate G on which the semiconductor layer 220 is grown at preset intervals to manufacture a plurality of epitaxy dies. That is, the epitaxial die in the present invention means that the initial growth substrate G on which the semiconductor layer 220 is epitaxially grown is cut (diced) into a plurality of dies and sorted according to characteristics.

Typically, since silicon (Si), diamond, silicon carbide (SiC), or aluminum nitride (AlN) final support substrate 210 wafer having high heat dissipation conductivity characteristics has a difference in CTE from the sapphire initial growth substrate G as large as 2 ppm or more, although it is preferable to perform an annealing process at a predetermined temperature of 300° C. or higher during the W2W bonding process or after the above process is completed, this is realistically impossible. Therefore, the W2W bonding process generally introduces an intermediate bonding layer 250 between wafers to bond dielectric materials (SiO2, SOG, HSQ, SiN, SiCN, AlN, SiC, diamond, or Al2O3), and in this case, strict conditions such as zero foreign substances (particles) on the surfaces of the two wafers, minimizing a total thickness variation (TTV), and ensuring that surface roughness is less than 0.5 nm should be satisfied at the same time, which may not be easily implemented.

Therefore, in the present invention, first, the plurality of epitaxy dies may be manufactured by cutting the initial growth substrate G on which the semiconductor layer 220 is grown, and then the plurality of epitaxy dies may each be bonded on the final support substrate 210 wafer having high dissipation performance through the intermediate temporary substrate T (die to wafer (D2W)), and therefore, the effect of the CTE between the small epitaxy dies and the relatively large final support substrate 210 wafer can be minimized, making it easy to manufacture a high-quality group III nitride power semiconductor device.

The third operation S230 is an operation of bonding each of the semiconductor layers 220 of the plurality of epitaxy dies to the intermediate temporary substrate T through an adhesive layer 240. That is, the third operation S230 is an operation of turning over the plurality of epitaxy dies and pressing and bonding the semiconductor layers 220 to the intermediate temporary substrate T at a temperature of lower than 300° C. For example, the semiconductor layer 220 may be bonded to the intermediate temporary substrate T by forming a first adhesive layer on the semiconductor layer 220, that is, the barrier layer 222, forming a second adhesive layer on the intermediate temporary substrate T, and then adhering the first adhesive layer to the second adhesive layer to form the adhesive layer 240, and the semiconductor layer 220 may be adhered to the intermediate temporary substrate T after the adhesive layer 240 is formed only on the semiconductor layer 220 or the intermediate temporary substrate T.

In addition, the adhesive layer 240 may contain materials such as silicon oxide (SiO2), SOG, flowable oxide (FOx), silicon nitride (SiNx), aluminum oxide (Al2O3), aluminum nitride (AlN), and silicon carbon nitride (SiCN) as a dielectric material capable of direct bonding at a temperature of 100° C. or lower and contain materials such as resin, benzocyclobutene (BCB), and polyimide (PI) as an organic adhesive capable of indirect bonding at a temperature of 100° C. or lower.

Meanwhile, the optically transparent intermediate temporary substrate T is a substrate that is finally easily separated by an LLO technique in the subsequent process, and the sacrificial layer 230 may be deposited on the intermediate temporary substrate T before forming the adhesive layer 240, and a material for the sacrificial layer 230 may contain an oxide, a nitride, etc. that may be deposited by a physical vapor deposition (PVD) technique such as sputtering, pulsed laser deposition (PLD), or an evaporator, specifically, contain a material such as indium tin oxide (ITO), gallium oxide (GaOx), gallium oxide nitride (GaON), gallium nitride (GaN), indium gallium nitride (InGaN), tin oxide (ZnO), indium gallium tin oxide (InGaZnO), indium tin oxide (InZnO), or indium gallium oxide (InGaO),

The fourth operation S240 is an operation of separating the initial growth substrate G from the buffer layer 221 using an LLO technique. The buffer layer 221 exposed by separating the initial growth substrate G has a nitrogen polar surface (N-polar surface).

Here, the LLO technique is a technique of separating an epitaxy-grown layer from the initial growth substrate G by irradiating a back surface of the transparent initial growth substrate G with an ultraviolet (UV) laser beam having a uniform optical output and beam profile, and a single wavelength. When the initial growth substrate G is separated, the inside of the semiconductor layer 220 transferred onto the final support substrate 210 is in a state in which the stress is completely relieved and maintains a flat state together with the final support substrate 210. Then, planarization is achieved by removing the sacrificial layer 230 damaged due to the separation of the initial growth substrate G, contaminated surface residues, a low-quality single crystalline thin film region, etc. through CMP, dry etching, etc.

The fifth operation S250 is an operation of bonding surfaces of the semiconductor layers 220 of the plurality of epitaxy dies from which the initial growth substrate G is separated to the support substrate 210 through the bonding layer 250. That is, the fifth operation S250 is an operation of turning over the intermediate temporary substrate T to which the plurality of epitaxy dies are adhered and pressing and bonding the semiconductor layer 220 to the final support substrate 210 at a temperature of lower than 300° C. For example, the semiconductor layer 220 may be bonded to the final support substrate 210 by forming a first bonding layer on the semiconductor layer 220, that is, the buffer layer 221, forming a second bonding layer on the final support substrate 210, and then bonding the first bonding layer to the second bonding layer to form the bonding layer 250, and the semiconductor layer 220 may be bonded to the final support substrate 210 after the bonding layer 250 is formed only on the semiconductor layer 220 or the final support substrate 210.

Conventionally, epitaxy wafer bowing occurs due to thermo-mechanical induced tensile stress caused by the differences in LC and CTE between the initial growth substrate G and the group III nitride semiconductor, but the epitaxy die bonded to the final support substrate 210 through the intermediate temporary substrate T according to the present invention may be in a stress-relieved state, thereby minimizing wafer bowing to almost zero. In this case, it is possible to minimize stress by setting a bonding process temperature to about room temperature and performing the process, thereby further minimizing wafer bowing.

In addition, for the bonding layer 250, a dielectric material whose properties do not change and which has excellent thermal conductivity in the MOCVD chamber (at a temperature of 1000° C. or higher and in a reducing atmosphere) in which the group III nitride semiconductor is grown may be preferentially selected, and for example, silicon oxide (SiO2, 0.8 ppm), silicon nitride (SiNx, 3.8 ppm), silicon carbon nitride (SiCN, 3.8 to 4.8 ppm), aluminum nitride (AlN, 4.6 ppm), silicon carbide (SiC, 4.2 ppm), diamond (1.2 ppm), aluminum oxide (Al2O3, 6.8 ppm) may be selected, and furthermore, a flowable oxide (FOx) such as SOG (liquid SiO2) or HSQ may be selected to improve surface roughness.

Meanwhile, the reinforcement layer 260 may be formed between the bonding layer 250 and the semiconductor layer 220 or between the bonding layer 250 and the final support substrate 210.

In this case, although a case where the reinforcement layer 260 is formed between the bonding layer 250 and the semiconductor layer 220 is not shown, in the fourth operation S240 and the fifth operation S250, after the initial growth substrate G is separated from the semiconductor layer 220, the reinforcement layer 260 may be formed on the semiconductor layer 220 (i.e., the buffer layer 221), and the reinforcement layers 260 of the plurality of epitaxy dies may be bonded to the final support substrate 210 through the bonding layer 250 (see the top figure of FIG. 8).

In addition, although a case where the reinforcement layer 260 is formed between the bonding layer 250 and the final support substrate 210 is not shown, in the fifth operation S250, the semiconductor layers 220 of the plurality of epitaxy dies may be bonded to the reinforcement layer 260 through the bonding layer 250 by forming the reinforcement layer 260 on the final support substrate 210 and then forming the bonding layer 250 on the reinforcement layer 260 (see the middle figure of FIG. 8).

Here, more specifically, the reinforcement layer 260 includes a bonding reinforcement layer 261 and a compressive stress layer 262, and since the contents of the bonding reinforcement layer 261 and the compressive stress layer 262 are the same as those of the above-described method of manufacturing a group III nitride power semiconductor device using epitaxy dies according to the first embodiment of the present invention, overlapping descriptions thereof will be omitted.

Meanwhile, as shown in FIG. 8, in the present invention, in some cases, the reinforcement layer 260 may be disposed between the bonding layer 250 and the semiconductor layer 220 or formed between the bonding layer 250 and the final support substrate 210, and the reinforcement layer 260 may be formed between the bonding layer 250 and the semiconductor layer 220 and between the bonding layer 250 and the final support substrate 210. In addition, the bonding reinforcement layer 261 or the compressive stress layer 262 may be omitted from the reinforcement layer 260, and a case where the reinforcement layer 260 between the bonding layer 250 and the final support substrate 210 is omitted and the bonding layer 250 is directly bonded to the final support substrate 210 may be a structure in which a material having a larger CTE than the final support substrate 210, such as silicon (Si), is deposited on the bonding layer 250 to induce compressive stress together with a bonding function.

The sixth operation S260 is an operation of separating the intermediate temporary substrate T from the sacrificial layer 230 using an LLO technique.

The seventh operation S270 is an operation of etching and removing the sacrificial layer 230 and the adhesive layer 240 and etching the bonding layer 250 to set the size of the chip die. As the adhesive layer 240 is etched and removed, the exposed barrier layer 222 has a group 3 metal polar surface (M-polar surface) such as gallium (Ga).

The eighth operation S280 is an operation of forming a plurality of electrodes 270 on each epitaxy die according to the power semiconductor structure such as a transistor (three electrodes 270) or a diode (two electrodes 270) on the barrier layer 222 of the bonded semiconductor layer 220, forming a passivation layer as needed, then performing annealing for an ohmic contact or Schottky contact, and then thinning and cutting the final support substrate 210 to manufacture a power semiconductor device, which means a plurality of chip dies or IC dies.

A group III nitride power semiconductor device manufactured by the method S200 of manufacturing a group III nitride power semiconductor device using epitaxy dies according to the second embodiment of the present invention may have a structure in which the final support substrate 210, the bonding layer 250, the buffer layer 221, and the barrier layer 222 are sequentially stacked, have a structure in which the reinforcement layer 260 is formed between the bonding layer 250 and the final support substrate 210 or between the bonding layer 250 and the buffer layer 221, and have a structure in which the plurality of electrodes 270 or the passivation layer is formed on an upper surface of the barrier layer 222.

A method S300 of manufacturing a group III nitride power semiconductor device using epitaxy dies according to a third embodiment of the present invention will now be described in detail with reference to the accompanying drawings.

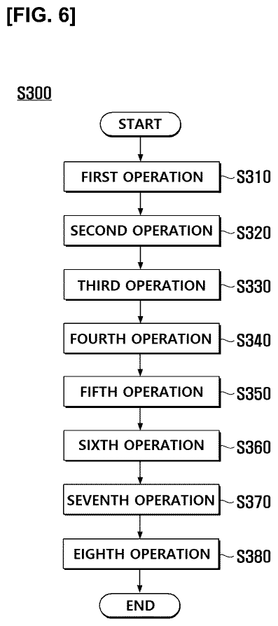

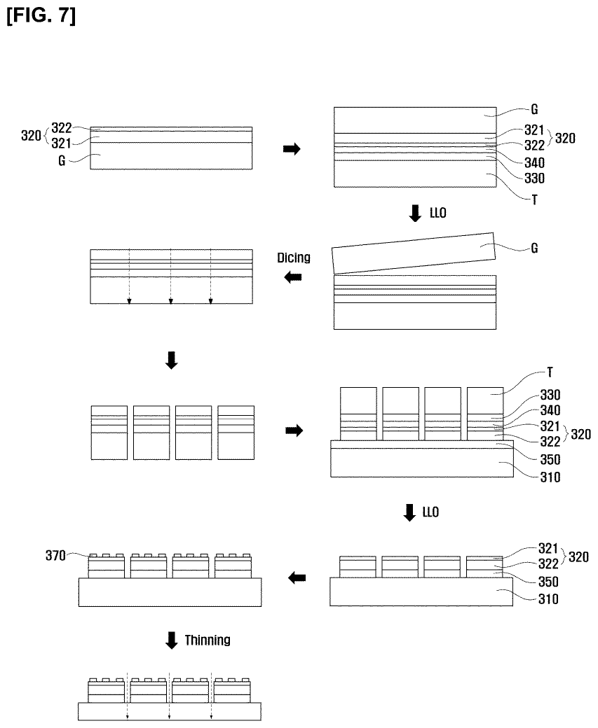

FIG. 6 is a flowchart of a method of manufacturing a group III nitride power semiconductor device using epitaxy dies according to a third embodiment of the present invention, FIG. 7 shows a process of manufacturing a group III nitride power semiconductor device using epitaxy dies according to the third embodiment of the present invention, and FIG. 8 shows a reinforcement layer 360 differently disposed on the group III nitride power semiconductor device manufactured according to the second embodiment or third embodiment of the present invention.

As shown in FIGS. 6 and 7, the method S300 of manufacturing a group III nitride power semiconductor device using epitaxy dies according to the third embodiment of the present invention includes a first operation S310, a second operation S320, a third operation S330, a fourth operation S340, a fifth operation S350, a sixth operation S360, a seventh operation S370, and an eighth operation S380.

Since the contents of the initial growth substrate G, the intermediate temporary substrate T, the final support substrate 310, and the first operation S310 in the present embodiment are the same as those of the above-described method of manufacturing a group III nitride power semiconductor device using epitaxy dies according to the second embodiment of the present invention, overlapping descriptions thereof will be omitted.

The second operation S320 is an operation of adhering a semiconductor layer 320 to the intermediate temporary substrate T through an adhesive layer 340. That is, the third operation S330 is an operation of turning over the initial growth substrate G on which the semiconductor layer 320 is grown and pressing and bonding the semiconductor layer 320 to the intermediate temporary substrate T at a temperature of lower than 300° C. For example, the semiconductor layer 320 may be bonded to the intermediate temporary substrate T by forming a first adhesive layer on the semiconductor layer 320, that is, a barrier layer 322, forming a second adhesive layer on the intermediate temporary substrate T, and then adhering the first adhesive layer to the second adhesive layer to form the adhesive layer 340, and the semiconductor layer 320 may be adhered to the intermediate temporary substrate T after the adhesive layer 340 is formed only on the semiconductor layer 320 or the intermediate temporary substrate T.

Meanwhile, the optically transparent intermediate temporary substrate T is a substrate that is finally easily separated by an LLO technique in the subsequent process, and a sacrificial layer 330 may be deposited on the intermediate temporary substrate T before forming the adhesive layer 340, and a material for the sacrificial layer 330 may contain an oxide, a nitride, etc. that may be deposited by a physical vapor deposition (PVD) technique such as sputtering, pulsed laser deposition (PLD), or an evaporator, specifically, contain a material such as indium tin oxide (ITO), gallium oxide (GaOx), gallium oxide nitride (GaON), gallium nitride (GaN), indium gallium nitride (InGaN), tin oxide (ZnO), indium gallium tin oxide (InGaZnO), indium tin oxide (InZnO), or indium gallium oxide (InGaO),

The third operation S330 is an operation of separating the initial growth substrate G from a buffer layer 321 using an LLO technique. The buffer layer 321 exposed by separating the initial growth substrate G has a nitrogen polar surface (N-polar surface).

The fourth operation S340 is an operation of cutting the intermediate temporary substrate T to which the semiconductor layer 320 is adhered at preset intervals to manufacture a plurality of epitaxy dies. That is, the epitaxial die in the present invention means that the intermediate temporary substrate T to which the semiconductor layer 320 is adhered is cut (diced) into a plurality of dies and sorted according to characteristics.

Typically, since silicon (Si), silicon carbide (SiC), or aluminum nitride (AlN) final support substrate 310 wafer having high heat dissipation characteristics has a difference in CTE from the sapphire initial growth substrate G as large as 2 ppm or more, although it is preferable to perform an annealing process at a predetermined temperature of 300° C. or higher during the W2W bonding process or after the above process is completed, this is realistically impossible. Therefore, the W2W bonding process generally introduces an intermediate bonding layer 350 between wafers to bond dielectric materials (SiO2, SOG, HSQ, SiN, SiCN, AlN, SiC, diamond, or Al2O3), and in this case, strict conditions such as zero foreign substances (particles) on the surfaces of the two wafers, minimizing a total thickness variation (TTV), and ensuring that surface roughness is less than 0.5 nm should be satisfied at the same time, which may not be easily implemented.

Therefore, in the present invention, first, the plurality of epitaxy dies may be manufactured by cutting the intermediate temporary substrate T to which the semiconductor layer 320 is adhered, and then the plurality of epitaxy dies may be bonded on the final support substrate 310 wafer having high heat dissipation performance (die to wafer (D2W)), and therefore, the effect of the CTE between the small epitaxy dies and the relatively large final support substrate 310 wafer can be minimized, making it easy to manufacture the high-quality group III nitride power semiconductor device.

The fifth operation S350 is an operation of bonding surfaces of the semiconductor layers 320 of the plurality of epitaxy dies from which the growth substrate G is separated to the support substrate 310 through the bonding layer 350.

Meanwhile, the reinforcement layer 360 may be formed between the bonding layer 350 and the semiconductor layer 320 or between the bonding layer 350 and the final support substrate 310. Here, more specifically, the reinforcement layer 360 includes a bonding reinforcement layer 361 and a compressive stress layer 362.

In this case, although a case where the reinforcement layer 360 is formed between the bonding layer 350 and the semiconductor layer 320 is not shown, in the fourth operation S340 and the fifth operation S350, after the initial growth substrate G is separated from the semiconductor layer 320, the reinforcement layer 360 may be formed on the semiconductor layer 320 (i.e., the buffer layer 321), and the reinforcement layers 360 of the plurality of epitaxy dies may be bonded to the final support substrate 310 through the bonding layer 350 (see the top figure of FIG. 8).

In addition, although a case where the reinforcement layer 360 is formed between the bonding layer 350 and the final support substrate 310 is not shown, in the fifth operation S350, the semiconductor layers 320 of the plurality of epitaxy dies may be bonded to the reinforcement layer 360 through the bonding layer 350 by forming the reinforcement layer 360 on the final support substrate 310 and then forming the bonding layer 350 on the reinforcement layer 360 (see the middle figure of FIG. 8).

Since the contents that have not been described in detail in the second operation S320 to the fifth operation S350 are the same as those of the above-described method of manufacturing the group III nitride power semiconductor device using epitaxy dies according to the second embodiment of the present invention, overlapping descriptions thereof will be omitted.

The sixth operation S360 is an operation of separating the intermediate temporary substrate T from the sacrificial layer 330 using an LLO technique.

The seventh operation S370 is an operation of etching and removing the sacrificial layer 330 and the adhesive layer 340 and etching the bonding layer 350 to set the size of the chip die. As the adhesive layer 340 is removed by being etched, the exposed barrier layer 322 has a group 3 metal polar surface (M-polar surface) such as gallium (Ga).

The eighth operation S380 is an operation of forming a plurality of electrodes 370 on each epitaxy die according to the power semiconductor structure such as a transistor (three electrodes 370) or a diode (two electrodes 370) on the barrier layer 322 of the bonded semiconductor layer 320, forming a passivation layer as needed, then performing annealing for an ohmic contact or Schottky contact, and then thinning and cutting the final support substrate 310 to manufacture a power semiconductor device, which means a plurality of chip dies or IC dies.

A group III nitride power semiconductor device manufactured by the method S300 of manufacturing a group III nitride power semiconductor device using epitaxy dies according to the third embodiment of the present invention may have a structure in which the final support substrate 310, the bonding layer 350, the buffer layer 321, and the barrier layer 322 are sequentially stacked, have a structure in which the reinforcement layer 360 is formed between the bonding layer 350 and the final support substrate 310 or between the bonding layer 350 and the buffer layer 321, and have a structure in which the plurality of electrodes 370 or the passivation layer is formed on an upper surface of the barrier layer 322.

As described above, although all the components constituting embodiments disclosed herein were described as being combined or combined to operate as one, the present invention is not necessarily limited to these embodiments. That is, one or more of all the components may be combined to operate as one without departing from the scope of the purpose of the present invention.

In addition, the terms such as “comprise,” “constitute,” or “have” described above mean that the corresponding component may be inherent unless otherwise stated, and thus should be construed as further including another component rather than excluding another component. All terms including technical or scientific terms have the same meaning as commonly understood by those skilled in the art to which the present invention pertains unless defined otherwise. Commonly used terms, such as terms defined in a dictionary, should be intended as being consistent with the contextual meaning of the related art and are not interpreted in an ideal or excessively formal meaning unless explicitly defined herein.

In addition, the above description is merely the exemplary description of the technical spirit of the present invention, and those skilled in the art to which the present invention pertains will be able to variously modify and change the present invention without departing from the essential characteristics of the present invention.

Therefore, the embodiments disclosed in the present invention are not intended to limit the technical spirit of the present invention, but intended to describe the same, and the scope of the technical spirit of the present invention is not limited by these embodiments. The scope of the present invention should be construed by the appended claims, and all technical ideas within the equivalent scope should be construed as being included in the scope of the present invention.

1. A method of manufacturing a group III nitride power semiconductor device using epitaxy dies, the method comprising:
a first operation of epitaxially growing a semiconductor layer on a growth substrate;
a second operation of cutting the growth substrate on which the semiconductor layer is grown to manufacture a plurality of dies;
a third operation of bonding the semiconductor layer of the die to a support substrate through a bonding layer;
a fourth operation of separating the growth substrate from the semiconductor layer; and
a fifth operation of cutting the support substrate to which the semiconductor layer is bonded to manufacture a power semiconductor device.

2. The method of claim 1, wherein a reinforcement layer, which increases bonding strength and induces compressive stress, is formed between the bonding layer and the semiconductor layer or between the bonding layer and the support substrate.

3. The method of claim 2, wherein the reinforcement layer includes a bonding reinforcement layer formed in contact with the bonding layer to increase bonding strength with the bonding layer and a compressive stress layer formed on the bonding reinforcement layer to induce compressive stress.

4. The method of claim 1, wherein the fifth operation includes forming a plurality of electrodes on the semiconductor layer.

5. The method of claim 1, wherein the fifth operation includes forming a passivation layer on the semiconductor layer.

6. The method of claim 1, wherein the semiconductor layer includes a buffer layer grown on the growth substrate and a barrier layer grown on the buffer layer.

7. A method of manufacturing a group III nitride power semiconductor device using epitaxy dies, the method comprising:
a first operation of epitaxially growing a semiconductor layer on a growth substrate;
a second operation of cutting the growth substrate on which the semiconductor layer is grown to manufacture a plurality of dies;
a third operation of adhering the semiconductor layer of the die to a temporary substrate through an adhesive layer;
a fourth operation of separating the growth substrate from the semiconductor layer;
a fifth operation of bonding a surface of the semiconductor layer from which the growth substrate is separated to a support substrate through a bonding layer;
a sixth operation of separating the temporary substrate from the adhesive layer;
a seventh operation of etching and removing the adhesive layer; and
an eighth operation of cutting the support substrate to which the semiconductor layer is bonded to manufacture a power semiconductor device.

8. The method of claim 7, wherein a reinforcement layer, which increases bonding strength and induces compressive stress, is formed between the bonding layer and the semiconductor layer or between the bonding layer and the support substrate.

9. The method of claim 8, wherein the reinforcement layer includes a bonding reinforcement layer formed in contact with the bonding layer to increase bonding strength with the bonding layer and a compressive stress layer formed on the bonding reinforcement layer to induce compressive stress.

10. The method of claim 7, wherein the eighth operation includes forming a plurality of electrodes on the semiconductor layer.

11. The method of claim 7, wherein the eighth operation includes forming a passivation layer on the semiconductor layer.

12. The method of claim 7, wherein the semiconductor layer includes a buffer layer grown on the growth substrate and a barrier layer grown on the buffer layer.

13. A method of manufacturing a group III nitride power semiconductor device using epitaxy dies, the method comprising:
a first operation of epitaxially growing a semiconductor layer on a growth substrate;
a second operation of adhering the semiconductor layer to a temporary substrate through an adhesive layer;
a third operation of separating the growth substrate from the semiconductor layer;
a fourth operation of cutting the temporary substrate to which the semiconductor layer is adhered to manufacture a plurality of dies;
a fifth operation of bonding a surface of the semiconductor layer of the die from which the growth substrate is separated to a support substrate through a bonding layer;
a sixth operation of separating the temporary substrate from the adhesive layer;
a seventh operation of etching and removing the adhesive layer; and
an eighth operation of cutting the support substrate to which the semiconductor layer is bonded to manufacture a power semiconductor device.

14. The method of claim 13, wherein a reinforcement layer, which increases bonding strength and induces compressive stress, is formed between the semiconductor layer and the bonding layer.

15. The method of claim 14, wherein the reinforcement layer includes a bonding reinforcement layer formed in contact with the bonding layer to increase bonding strength with the bonding layer and a compressive stress layer formed on the bonding reinforcement layer to induce compressive stress.

16. The method of claim 13, wherein the eighth operation includes forming a plurality of electrodes on the semiconductor layer.

17. The method of claim 13, wherein the eighth operation includes forming a passivation layer on the semiconductor layer.

18. The method of claim 13, wherein the semiconductor layer includes a buffer layer grown on the growth substrate and a barrier layer grown on the buffer layer.
